(19) United States
(12) Patent Application Publication
(10) Pub. No.: US 2025/0126954 A1
(43) Pub. Date: Apr. 17, 2025

(54) DISPLAY SUBSTRATE AND TRANSPARENT DISPLAY DEVICE

(71) Applicants: Hefei BOE Ruisheng Technology Co., Ltd., Hefei, Anhui (CN); BOE Technology Group Co., Ltd., Beijing (CN)

(72) Inventors: Tsungchieh KUO, Beijing (CN); Zouming XU, Beijing (CN); Xintao WU, Beijing (CN); Jianying ZHANG, Beijing (CN)

(21) Appl. No.: 18/577,658

(22) PCT Filed: Nov. 3, 2022
(86) PCT No.: PCT/CN2022/129417

§ 371 Date: Jan. 8, 2024

(51) Int. Cl. H10H 29/49

(52) U.S. Cl. CPC H10H 29/49

(57) ABSTRACT

Provided is a display substrate. The display substrate includes: a substrate; a first metal layer and a second metal layer on a side of the substrate, and a first insulating layer between the first and second metal layers; wherein the first metal layer includes a plurality of first drive signal lines, and the second metal layer includes a plurality of second drive signal lines; and a plurality of light-emitting units electrically connected to the plurality of first drive signal lines and the plurality of second drive signal lines; wherein at least a portion of each of the first drive signal lines and at least a portion of each of the second drive signal lines are grid-shaped signal lines.

### CROSS-REFERENCE TO RELATED APPLICATION

The present disclosure is a U.S. national stage of international application No. PCT/CN2022/129417, filed on Nov. 3, 2022, the content of which is herein incorporated by reference in its entirety.

### TECHNICAL FIELD

The present disclosure relates to the field of display technologies, in particular relates to a display substrate and a transparent display device.

### BACKGROUND

With the development of display technologies, various products with a transparent display function appear in daily life, such as outdoor billboards, shopping mall display panels, and transparent display screens.

### SUMMARY

Embodiments of the present disclosure provide a display substrate and a transparent display device. The technical solutions are summarized as follows:

According to some embodiments of the present disclosure, a display substrate is provided.

The display substrate includes: a substrate; a first metal layer and a second metal layer on a side of the substrate, and a first insulating layer between the first and second metal layers; wherein the first metal layer includes a plurality of first drive signal lines, and the second metal layer includes a plurality of second drive signal lines; and a plurality of light-emitting units electrically connected to the plurality of first drive signal lines and the plurality of second drive signal lines, wherein at least a portion of each of the first drive signal lines and at least a portion of each of the second drive signal lines are grid-shaped signal lines.

In some embodiments, an extension direction of the first drive signal lines is intersected with an extension direction of the second drive signal lines, and a portion of each of the first drive signal lines that is overlapped with each of the second drive signal lines in an orthographic projection is the grid-shaped signal line.

In some embodiments, a portion of each of the second drive signal lines that is overlapped with each of the first drive signal lines in an orthographic projection is the grid-shaped signal line.

In some embodiments, the second metal layer further includes a plurality of pads electrically connected to the light-emitting units, and a first adapter signal line; wherein one end of the first adapter signal line being electrically connected to a first pad among the plurality of pads, and the other end of the first adapter signal line being electrically connected to the first drive signal line; and at least a portion of the first adapter signal line is the grid-shaped signal line.

In some embodiments, the first metal layer further includes a first electrode block electrically connected to the first drive signal line and connected to an end, facing away from the first pad, of the first adapter signal line.

In some embodiments, the second metal layer further includes a second electrode block electrically connected to the end, facing away from the first pad, of the first adapter signal line, and the second electrode block is electrically connected to the first electrode block.

In some embodiments, the first insulating layer is provided with a first via; an orthographic projection of the first via on the substrate is within an orthographic projection of the first electrode block on the substrate; and at least a portion of the second electrode block is within the first via and electrically connected to the first electrode block.

In some embodiments, the second metal layer further includes a second adapter signal line; wherein one end of the second adapter signal line is electrically connected to a second pad among the plurality of pads, and the other end of the second adapter signal line is electrically connected to the second drive signal line; and at least a portion of the second adapter signal line is the grid-shaped signal line.

In some embodiments, the second metal layer further includes a third adapter signal line; wherein both ends of the third adapter signal line are electrically connected to a third pad and a fourth pad of the plurality of pads respectively; and at least a portion of the third adapter signal line is the grid-shaped signal line.

In some embodiments, the light-emitting unit includes a chip and at least one light-emitting diode; and the plurality of pads include a first fixed pad group configured to be fixedly connected to the light-emitting diode, and a second fixed pad group configured to be fixedly connected to the chip; wherein the first pad and the third pad are distributed in the first fixed pad group, and the first pad, the second pad and the fourth pad are distributed in the second fixed pad group.

In some embodiments, an overlapping region is present between an orthographic projection of at least one of the first fixed pad group and the second fixed pad group on the substrate and an orthographic projection of the first drive signal line on the substrate.

In some embodiments, the plurality of first drive signal lines include an anode drive signal line, a data signal line, and a ground line; and the plurality of second drive signal lines include a power signal line. The first pad of the first fixed pad group is electrically connected to the anode drive signal line by the first adapter signal line; the third pad of the first fixed pad group is electrically connected to the fourth pad of the second fixed pad group by the third adapter signal line; one first pad of the second fixed pad group is electrically connected to the data signal line by one first adapter signal line, and another first pad of the second fixed pad group is electrically connected to the ground line by another first adapter signal line; and the second pad of the second fixed pad group is electrically connected to the power signal line by the second adapter signal line.

In some embodiments, the display substrate further includes a second insulating layer disposed on a side of the second metal layer deviating from the substrate; the second insulating layer is provided with a plurality of second vias corresponding one-to-one to the plurality of pads; and orthographic projections of the second vias on the substrate are within orthographic projections of the corresponding pads on the substrate.

In some embodiments, the first metal layer further includes a virtual signal line disposed between two adjacent the first drive signal lines, at least a portion of the virtual signal line being the grid-shaped signal line.

According to some embodiments of the present disclosure, a transparent display device is provided. The transparent display device includes a power supply assembly and a display substrate electrically connected to the power supply assembly, the display substrate being any one of the above-mentioned display substrates.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description illustrate merely some embodiments of the present disclosure, and persons of ordinary skill in the art may still derive other drawings from these accompanying drawings without creative efforts.

FIG. 1 is a top view of a display substrate according to some embodiments of the present disclosure;

FIG. 2 is a schematic diagram of a cross-section of the display substrate illustrated in FIG. 1 at A-A′;

FIG. 3 is a top view of another display substrate according to some embodiments of the present disclosure;

FIG. 4 is a schematic diagram of a cross-section of the display substrate illustrated in FIG. 3 at B-B′;

FIG. 5 is a top view of yet another display substrate according to some embodiments of the present disclosure;

FIG. 6 is a top view of yet another display substrate according to some embodiments of the present disclosure;

FIG. 7 is a schematic diagram of a cross-section of the display substrate illustrated in FIG. 3 at C-C′; and

FIG. 8 is a partial top view of a display substrate according to some embodiments of the present disclosure.

### DETAILED DESCRIPTION

To make the objectives, technical solutions, and advantages of the present disclosure clearer, the following further describes implementations of the present disclosure in detail with reference to the accompanying drawings.

The transparent display device typically includes a substrate and a plurality of light-emitting diodes arrayed on the substrate. Since the light-emitting diodes distributed on the substrate are opaque, in order to improve a transparency of the transparent display device, a distance between any two adjacent light-emitting diodes needs to be increased to ensure that external light is transmittable through an area between the two adjacent light-emitting diodes. Herein, the substrate typically includes a drive signal line to which the light-emitting diode is electrically connected, such that a drive signal transmitted over the drive signal line drives the light-emitting diode to emit light.

However, the drive signal lines in current transparent display devices have a low transmittance of light, which leads to a low transparency of the transparent display device.

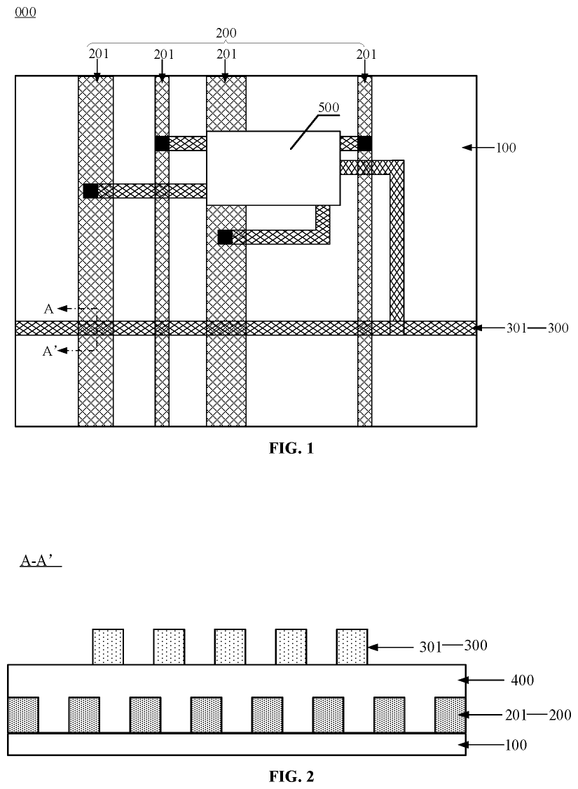

FIG. 1 is a top view of a display substrate according to some embodiments, and FIG. 2 is a schematic diagram of a cross-section of the display substrate illustrated in FIG. 1 at A-A′ As illustrated in FIG. 1 and FIG. 2, the display substrate 000 includes a substrate 100, a first metal layer 200, a second metal layer 300, a first insulating layer 400, and a light-emitting unit 500.

The first metal layer 200 and the second metal layer 300 in the display substrate 000 are disposed on a side of the substrate 100, and the first insulating layer 400 in the display substrate 000 is disposed between the first metal layer 200 and the second metal layer 300. Herein, the first insulating layer 400 is configured to insulate the first metal layer 200 from the second metal layer 300 to prevent a short circuit between the first metal layer 200 and the second metal layer 300.

As illustrated in FIG. 1, the first metal layer 200 in the display substrate 000 includes a plurality of first drive signal lines 201, and the second metal layer 300 in the display substrate 000 includes a plurality of second drive signal lines 301. The first drive signal lines 201 and the second drive signal lines 301 in the display substrate 000 are configured to be electrically connected to the light-emitting unit 500. The first drive signal lines 201 and the second drive signal lines 301 in the display substrate 000 supply a drive signal to the light-emitting unit 500, such that the light-emitting unit 500 is driven to emit light.

In the present disclosure, at least a portion of each of the first drive signal lines 201 and at least a portion of each of the second drive signal lines 301 in the display substrate 000 are the grid-shaped signal lines. As schematically illustrated in FIG. 1, the first drive signal lines 201 are the grid-shaped signal lines and the second drive signal lines 301 are the grid-shaped signal lines. In some other embodiments, in the display substrate 000, a portion of each of the first drive signal lines 201 is the grid-shaped signal line and a portion is a normal metal signal line, or a portion of each of the second drive signal lines 301 is the grid-shaped signal line and a portion is the normal metal signal line.

In the case that at least a portion of each of the first drive signal lines 201 and at least a portion of each of the second drive signal lines 301 in the display substrate 000 are the grid-shaped signal lines, areas of orthographic projections of the first drive signal lines 201 and the second drive signal lines 301 in the display substrate 000 on the substrate 100 is relatively small. Therefore, the first drive signal lines 201 and the second drive signal lines 301 have low reflectivity to ambient light, such that a black matrix for shielding the signal lines does not need to be integrated in the display substrate 000. Thus, the external light emitted to the display substrate 000 is not blocked by the black matrix, and a portion of the external light emitted to the grid-shaped signal lines in a light-transmitting backplane 000 is capable of running through. Therefore, in the case that the display substrate 000 is integrated in the transparent display device, a transmittance of the transparent display device to ambient light is effectively improved, such that the transparency of the transparent display device is higher. Furthermore, in the case that the black matrix does not need to be integrated in the display substrate 000, difficulty in manufacturing the display substrate 000 is lowered, and manufacturing cost of the display substrate 000 is reduced.

In summary, the display substrate according to the embodiments of the present disclosure includes a substrate, a first metal layer, a second metal layer, a first insulating layer, and a light-emitting unit. The first metal layer includes a plurality of first drive signal lines, and the second metal layer includes a plurality of second drive signal lines. Since at least a portion of each of the first drive signal lines and at least a portion of each of the second drive signal lines are the grid-shaped signal lines, areas of the orthographic projections of the first drive signal lines and the second drive signal lines in the display substrate on the substrate are smaller. Thus, in the case that the display substrate is integrated within the transparent display device, the transmittance of the transparent display device to ambient light is effectively improved, and thus a higher transparency of the transparent display device with the display substrate integrated is achieved. Moreover, the first drive signal line and the second drive signal line within the display substrate have a lower reflection rate of the ambient light, and thus the integration of a black matrix within the display substrate is not necessary, which lowers difficulty in manufacturing the display substrate and reduces manufacturing cost of the display substrate.

In the embodiments of the present disclosure, the first drive signal lines 201 in the display substrate 000 are arranged in parallel, and the second drive signal lines 301 are also arranged in parallel. Herein, an extension direction of the first drive signal lines 201 is intersected with an extension direction of the second drive signal lines 301. Exemplarily, the extension direction of the first drive signal lines 201 is perpendicular to the extension direction of the second drive signal lines 301.

In some practices, the first drive signal lines and the second drive signal lines with extension directions intersected are similarly integrated within the transparent display device. However, since these drive signal lines are ordinary signal lines of uniform line width, the first drive signal lines and the second drive signal lines have larger overlapping areas. Thus, in the case that moisture is present in insulating layers between the first drive signal lines and the second drive signal lines, metal ions in the first drive signal lines and the second drive signal lines are prone to migrate and grow, thereby damaging the insulating layers between the first drive signal lines and the second drive signal lines, resulting in an undesirable phenomenon of a short circuit being easily generated between the first drive signal lines and the second drive signal lines. Moreover, in the case that the areas over which the first drive signal lines and the second drive signal lines are overlapped are large, parasitic capacitances between the first drive signal lines and the second drive signal lines are large, and the parasitic capacitances cause interference to the drive signals transmitted over the first drive signal lines and the second drive signal lines, resulting in a poor display effect of the transparent display device.

Further, in some practices, in order to reduce the above-described undesirable phenomenon, it is necessary to ensure that the line width of the portion of the first drive signal line that is overlapped with the second drive signal line is smaller than the line width of other portions of the first drive signal line, and similarly, it is necessary to ensure that the line width of the portion of the second drive signal line that is overlapped with the first drive signal line is smaller than the line width of other portions of the second drive signal line. In this way, each of the drive signal lines belongs to a signal line with an uneven line width, and in the process of forming the signal lines with the uneven line width by an etching process, it is extremely easy to etch off the portions of these signal lines with smaller line widths, resulting in a poorer yield of the etching of the signal lines.

Referring to FIGS. 1 and 2 again, in some embodiments of the present disclosure, a portion of the first drive signal line 201 in the display substrate 000 that is overlapped with an orthographic projection of the second drive signal line 301 is the grid-shaped signal line. In this way, an area in which the first drive signal line 201 is overlapped with the second drive signal line 301 in the display substrate 000 is small. Therefore, in the display substrate 000, the probability of the undesirable phenomenon of the short circuit between the first drive signal line 201 and the second drive signal line 301 is lowered, and it is also ensured that a parasitic capacitance between the first drive signal line 201 and the second drive signal line 301 is smaller, such that the parasitic capacitance between the first drive signal line 201 and the second drive signal line 301 causes less interference to the drive signals transmitted over the first drive signal line 201 and the second drive signal line 301, ensuring the display effect of the transparent display device integrating the display substrate 000.

Further, a portion of the second drive signal line 301 in the display substrate 000 that is overlapped with an orthographic projection of the first drive signal line 201 is also the grid-shaped signal line. In this way, the area in which the first drive signal line 201 is overlapped with the second drive signal line 301 in the display substrate 000 is smaller, which further reduces the probability of the undesirable phenomenon of the short-circuit between the first drive signal line 201 and the second drive signal line 301 in the display substrate 000, and also further reduces interference caused by the parasitic capacitance to the drive signals transmitted over the drive signal lines.

In one possible implementation, all of the first drive signal lines 201 within the display substrate 000 are the grid-shaped signal lines, and all of the second drive signal lines 30 are the grid-shaped signal lines. In this way, it is ensured that the line widths at various positions in the first drive signal lines 201 are uniformly distributed, and the line widths at various positions in the second drive signal line 301 are also uniformly distributed. In this way, in a process of forming the signal lines by the etching process, the yield of etching the signal lines is effectively improved, such that the signal lines are less prone to the undesirable phenomenon of broken lines.

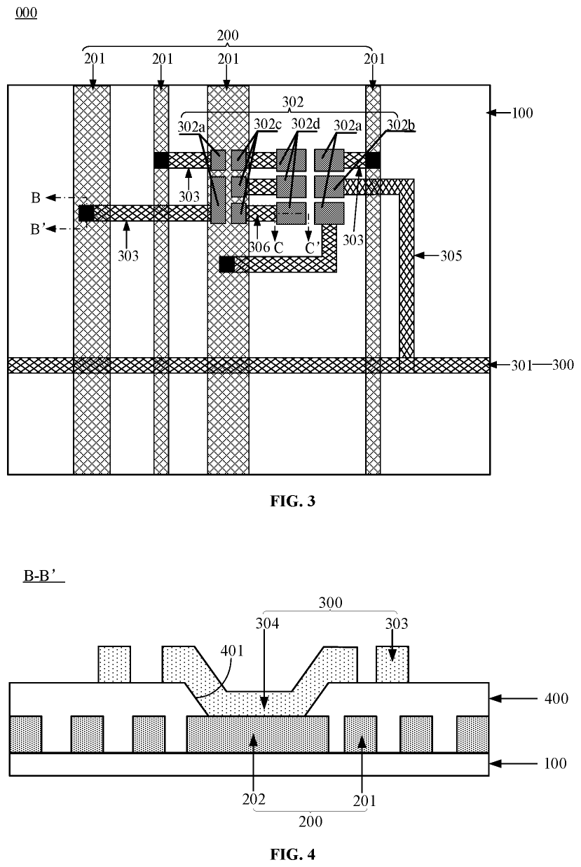

In some embodiments of the present disclosure, referring to FIG. 3, which is a top view of another display substrate according to some embodiments of the present disclosure, a second metal layer 300 in the display substrate 000 further includes: a plurality of pads 302 and a first adapter signal line 303. The plurality of pads 302 is configured to electrically connect to a light-emitting unit 500, and one end of the first adapter signal line 303 is electrically connected to the first pad 302a among the plurality of pads 302 and the other end of the first adapter signal line 303 is electrically connected to a first drive signal line 201. In this manner, a drive signal on the first drive signal line 201 is transmitted to the light-emitting unit 500 sequentially over the first adapter signal line 303 and the first pad 302a of the plurality of pads 302.

At least a portion of each of the first adapter signal lines 303 in the display substrate 000 is the grid-shaped signal line. As schematically illustrated in FIG. 3, all of the first adapter signal lines 303 are the grid-shaped signal lines. In some other embodiments, in the display substrate 000, a portion of each of the first adapter signal lines 303 is also the grid-shaped signal line and a portion is the normal metal signal line. Herein, in the case that at least a portion of each of the first adapter signal lines 303 in the display substrate 000 is the grid-shaped signal line, the transmittance of the display substrate 000 to the ambient light is further improved.

In the embodiments of the present disclosure, since both the plurality of pads 302 and the first adapter signal line 303 are a portion of the second metal layer 300, a direct electrical connection is made between a first solder pin 302a in the plurality of pads 302 and the first adapter signal line 303. The first drive signal line 201 belongs to a portion of the first metal layer 200, and the first insulating layer 400 is present between the first metal layer 200 and the second metal layer 300. Referring to FIG. 4, which is a schematic diagram of a cross-section of the display substrate illustrated in FIG. 3 at B-B′, in order to enable an electrical connection between the first drive signal line 201 and the first adapter signal line 303, it is necessary to provide a first via 401 within the first insulating layer 400, such that an end of the first adapter signal line 303 away from the first pad 302a is electrically connected to the first drive signal line 201 by this first via 401.

In the present disclosure, since both the first drive signal line 201 and the first adapter signal line 303 belong to the grid-shaped signal line, in order to ensure stable and effective transmission of the drive signals between the first adapter signal line 303 and the first drive signal line 201, the first metal layer 200 in the display substrate 000 also includes a first electrode block 202. Herein, the first electrode block 202 is electrically connected to the first drive signal line 201 and is electrically connected to an end portion of the first adapter signal line 303 away from the first pad 302a.

In this way, by providing the first electrode block 202 electrically connected to the first drive signal line 201 within the first metal layer 200, and allowing the first adapter signal line 303 to lap with the first electrode block 202, a lap area between the first adapter signal line 303 and the first drive signal line 201 is effectively increased, such that the electrical connection between the first adapter signal line 303 and the first drive signal line 201 is better. In this case, the drive signal on the first drive signal line 201 is transmittable to the light-emitting unit 500 sequentially over the first electrode block 202, the first adapter signal line 303, and the first pad 302a.

It is to be understood that the first drive signal line 201 have an opening region within the first electrode block 202, and the first electrode block 202 is distributed within the opening aperture region. Since the first drive signal line 201 are the grid-shaped drive signal line, thin lines within the grid-shaped drive signal line are fixedly connected to sidewalls of the first electrode block 202 to ensure that the two are electrically connected to each other.

Further, the second metal 300 layer in the display substrate 000 further includes a second electrode block 304. Herein, the second electrode block 304 is electrically connected to an end of the first adapter signal line 303 away from the first pad 302a, and the second electrode block 304 is electrically connected to the first electrode block 202. In this way, the overlapping area between the first adapter signal line 303 and the first drive signal line 201 is further increased to further improve the effect of the electrical connection between the first adapter signal line 303 and the first electrode block 202. In this case, the drive signal on the first drive signal line 201 is transmitted to the light-emitting unit 500 sequentially over the first electrode block 202, the second electrode block 304, the first adapter signal line 303 and the first pad 302a.

In the embodiments of the present disclosure, an orthographic projection of the first via 401 disposed within the first insulating layer 400 on the substrate 100 is within an orthographic projection of the first electrode block 202 on the substrate 100, and at least a portion of the second electrode block 304 is within the first via 401 and electrically connected to the first electrode block 202. That is, in the display substrate 000, at least a portion of the second electrode block 304 is in contact with the first electrode block 202 within the first via 401, such that the second electrode block 304 is electrically connected to the first electrode block 202 by the non-conductive first insulating layer 400.

In some embodiments, as illustrated in FIG. 3, the second metal layer 300 in the display substrate 000 further includes a second adapter signal line 305. One end of the second adapter signal line 305 is electrically connected to the second pad 302b among the plurality of pads 302, and the other end of the second adapter signal line 305 is electrically connected to the second drive signal line 301. Thus, the drive signal on the second drive signal line 301 is transmitted to the light-emitting unit 500 sequentially over the second adapter signal line 305 and the second pad 302b of the plurality of pads 302.

At least a portion of the second adapter signal line 305 in the display substrate 000 are the grid-shaped signal lines. As schematically illustrated in FIG. 3, the entire second adapter signal line 305 is the grid-shaped signal line. In some other embodiments, in the display substrate 000, a portion of the second adapter signal line 305 is the grid-shaped signal line and a portion is the normal metal signal line. Similarly, in the case that at least a portion of the second adapter signal line 305 in the display substrate 000 is the grid-shaped signal line, the transmittance of the display substrate 000 to the ambient light is further improved.

In the embodiments of the present disclosure, the plurality of pads 302, the second adapter signal line 305, and the second drive signal line 301 are all included in a portion of the second metal layer 300. Therefore, one end of the second adapter signal line 303 is directly electrically connected to the second pad 302b of the plurality of pads 302, and the other end of the second adapter signal line 303 is directly electrically connected to the second drive signal line 301.

In some embodiments, as illustrated in FIG. 3, the second metal layer 300 in the display substrate 000 further includes a third adapter signal line 306. Both ends of the third adapter signal line 306 are electrically connected to a third pad 302c and a fourth pad 302d of the plurality of pads 302 respectively.

At least a portion of the third adapter signal line 306 is the grid-shaped signal line. As schematically illustrated in FIG. 3, the entire third adapter signal line 306 is the grid-shaped signal line. In other embodiments, in the display substrate 000, a portion of the third adapter signal line 306 is also the grid-shape signal line, a portion is the normal metal signal line. Similarly, in the case that at least a portion of the third adapter signal line 306 in the display substrate 000 is the grid-shaped signal line, the transmittance of the display substrate 000 to the ambient light is further improved.

In the embodiments of the present disclosure, since both the plurality of pads 302 and the third adapter signal line 306 are a portion of the second metal layer 300, one end of the third adapter signal 306 is directly connected to the third pad 302c of the plurality of pads 302, and the other end of the third adapter signal 306 is directly connected to the fourth pad 302d of the plurality of pads 302.

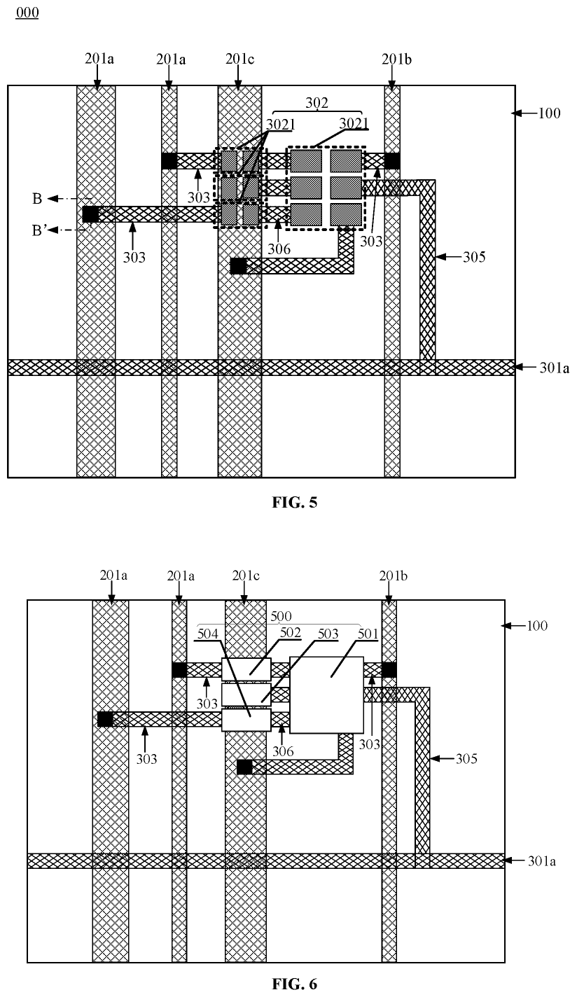

FIG. 5 is a top view of yet another display substrate according to some embodiments of the present disclosure, and FIG. 6 is a top view of yet another display substrate according to some embodiments of the present disclosure. A light-emitting unit 500 in the display substrate 000 includes a chip 501 and at least one light-emitting diode. In this case, a plurality of pads 302 distributed within a second metal layer 300 in the display substrate 000 include a first fixed pad group 3021 configured to fixedly connect to the light-emitting diode in the light-emitting unit 500, and a second fixed pad group 3022 configured to fixedly connect to the chip 501 in the light-emitting unit 500. With reference to FIG. 3 and FIG. 5, it can be seen that a first pad 302a and a third pad 302c are distributed within the first fixed pad group 3021, and the first pad 302a, a second pad 302b, and a fourth pad 302d are distributed within the second fixed pad group 3022. It is to be noted that the pad 302 within the display substrate illustrated in FIG. 6 is covered by the light-emitting unit 500, and therefore, in order to make it easy to see a distribution position of the pad 302 provided within the display substrate, the light-emitting unit 500 is not drawn within the display substrate illustrated in FIGS. 3 and 5.

In the present disclosure, an orthographic projection of at least one of the first fixed pad group 3021 and the second fixed pad group 3022 on the substrate 100 has an overlapping region with an orthographic projection of the first drive signal line 201 on the substrate 100. As schematically illustrated in FIG. 5, an orthographic projection of the first fixed pad group 3021 on the substrate 100 is within the orthographic projection of the first drive signal line 201 on the substrate 100, and an orthographic projection of the second fixed pad group 3022 on the substrate 100 does not have an overlapping region with the orthographic projection of the first drive signal line 201 on the substrate 100. It is to be understood that in the display substrate 000, it is also possible that an overlapping region is present between the orthographic projection of the second fixed pad group 3022 on the substrate 100 and the orthographic projection of the first drive signal line 201 on the substrate 100, and that no overlapping region is present between the orthographic projection of the first fixed pad group 3021 on the substrate 100 and the orthographic projection of the first drive signal line 201 on the substrate 100. Alternatively, the orthographic projections of the first fixed pad group 3021 and the second fixed pad group 3022 on the substrate 100 have overlapping regions with the orthographic projection of the first drive signal line 201 on the substrate 100, which is not limited by the embodiments of the present disclosure.

In the case that the orthographic projection of the first fixed pad group 3021 in the display substrate 000 on the substrate 100 has an overlapping region with the orthographic projection of the first drive signal line 201 on the substrate 100, it can be ensured that the orthographic projection of the light-emitting diode on the substrate 100 has an overlapping region with the orthographic projection of the first drive signal line 201 on the substrate 100 after the light-emitting diode is welded with the first fixed pad group 3021. In this case, since the light-emitting diode is light-impermeable and the first drive signal line 201 has a small overall transmittance of light, such the design ensures that the light-emitting diodes are not distributed between two adjacent first drive signal lines 201 that have a higher transmittance rate, thereby further improving the transparency of the transparent display device integrated with such display substrate 000.

Referring to FIGS. 3 and 5 again, in the embodiments of the present disclosure, the plurality of first drive signal lines 201 in the display substrate 000 include an anode drive signal line 201a, a data signal line 201b, and a ground line 201c; and the plurality of second drive signal lines 301 include a power signal line 301a.

The first pad 302a in the first fixed pad group 3021 is electrically connected to the anode drive signal line 201a by the first adapter signal line 303, and the third pad 302c in the first fixed pad group 3021 is electrically connected to the fourth pad 302d in the second fixed pad group 3022 by the third adapter signal line 306.

One first pad 302a in the second fixed pad group 3022 is electrically connected to the data signal line 201b by one first adapter signal line 303, and another first pad 302a in the second fixed pad group 3022 is electrically connected to the ground line 201c by another first adapter signal line 303.

The second pad 302b in the second fixed pad group 3022 is electrically connected to the power signal line 301a by the second adapter signal line 305.

Exemplarily, as illustrated in FIG. 6, the number of light-emitting diodes in the light-emitting unit 500 is three, and the three light-emitting diodes are, respectively, a red light-emitting diode 502 for emitting red light, a green light-emitting diode 503 for emitting green light, and a blue light-emitting diode 504 for emitting blue light. In this case, the number of the first fixing pad group 3021 is also three, and the three first fixing pad groups 3021 are fixedly connected to the red light-emitting diode 502, the green light-emitting diode 503, and the blue light-emitting diode 504 respectively.

Herein, the red light-emitting diode 502, the green light-emitting diode 503, and the blue light-emitting diode 504 in the light-emitting unit 500 all have two solder pins, which are a positive solder pin and a negative solder pin.

The positive solder pin of the red light-emitting diode 502 is welded to the first pad 302a in the corresponding first fixed pad group 3021, such that the positive solder pin of the red light-emitting diode 502 is connected to the corresponding anode drive line 201a by the first pad 302a and the corresponding first adapter line 303. The negative solder pin of the red light-emitting diode 502 is welded to the third pad 302c in the corresponding first fixed pad group 3021.

The positive solder pin of the green light-emitting diode 503 is welded to the first pad 302a in the corresponding first fixed pad group 3021, such that the positive solder pin of the green light-emitting diode 503 is connected to the corresponding anode drive line 201a by the first pad 302a and the corresponding first adapter line 303. The negative solder pin of the green light-emitting diode 503 is welded to the third pad 302c in a corresponding first fixed pad group 3021.

The positive solder pin of the blue light-emitting diode 504 is welded to the first pad 302a in the corresponding first fixed pad group 3021, such that the positive solder pin of the blue light-emitting diode 504 is connected to the corresponding anode drive line 201a by the first pad 302a and the corresponding first adapter line 303. The negative solder pin of the blue light-emitting diode 504 is welded to the third pad 302c in the corresponding first fixed pad group 3021.

The chip 501 in the light-emitting unit 500 has six solder pins, including a power signal input solder pin, a data signal input solder pin, a ground solder pin, and three signal output solder pins corresponding to three light-emitting diodes one by one.

The three signal output pins of the chip 501 are welded to three fourth pads 302d within the second fixed pad group 3022 respectively. Since the three fourth pads 302d are electrically connected to three third pads 302c in the three first fixed pad group 3021 respectively, by three third adapter signal lines 306, the three signal output solder pins of the chip 501 are electrically connected to the negative solder pins of three light-emitting diodes respectively.

The power signal input solder pin of the chip 501 is welded to one second pad 302b within the second fixed pad group 3022, such that the power signal input solder pin is connected to the power signal line 301a by the second pad 302b and the corresponding second adapter signal line 305.

The data signal input solder pin of the chip 501 is welded to one first pad 302a within the second fixed pad group 3022, such that the data signal input solder pin is connected to the data signal line 201b by the first pad 302a and the corresponding first adapter signal line 303.

The ground solder pin of the chip 501 is welded to another first pad 302a within the second fixed pad group 3022, such that the ground solder pin is connected to the ground line 201c by the first pad 302a and the corresponding first adapter signal line 303.

In this case that the display substrate 000 needs to control the light-emitting unit 500 to emit light, a power drive signal is applied to the power signal line 301a within the display substrate 000 electrically connected to the light-emitting unit 500, and a data drive signal is applied to the data signal line 201b electrically connected to the light-emitting unit 500. In this manner, after the chip 501 in the light-emitting unit 500 receives the power drive signal over the power signal input solder pin, the chip 501 is in an operating state. After the chip 501 receives the data signal over the data signal input solder pin, the chip 501 generates three cathode signals corresponding to the three light-emitting diodes one by one based on the data signal. The three cathode signals are transmittable to the negative solder pins of the three light-emitting diodes over the three signal output solder pins. Since the positive solder pin of the light-emitting diode is always connected to the anode signal applied by the anode drive signal line 201a, after the light-emitting diode receives the anode signal and the cathode signal respectively, the light-emitting diode emits light of corresponding intensity.

It should be noted that in order to simplify the wiring structure in the display substrate 000, at least two of the positive solder pin of the red light-emitting diode 502, the positive solder pin of the green light-emitting diode 503 and the positive solder pin of the blue light-emitting diode 504 are connected to the same anode drive line 201a. Since the light-emitting characteristics of the red light-emitting diode 502 differ greatly from those of the green light-emitting diode 503 and from those of the blue light-emitting diode 504, the light-emitting characteristics of the green light-emitting diode 503 differ little from those of the blue light-emitting diode 504, the positive solder pin of the green light-emitting diode 503 and the positive solder pin of the blue light-emitting diode 504 are connected to the same anode drive line 201a, and the positive solder pin of the red light-emitting diode 502 is connected to different anode drive lines 201a. In this case, the first pad 201a welded to the positive solder pin of the green light-emitting diode 503 and the first pad 201a soldered to the positive solder pin of the blue light-emitting diode 504 is an integral structure. That is, the positive solder pin of the green light-emitting diode 503 and the positive solder pin of the blue light-emitting diode 504 is welded to the same first pad 201a and the positive solder pin of the red light-emitting diode 502 is welded to another first pad 201a.

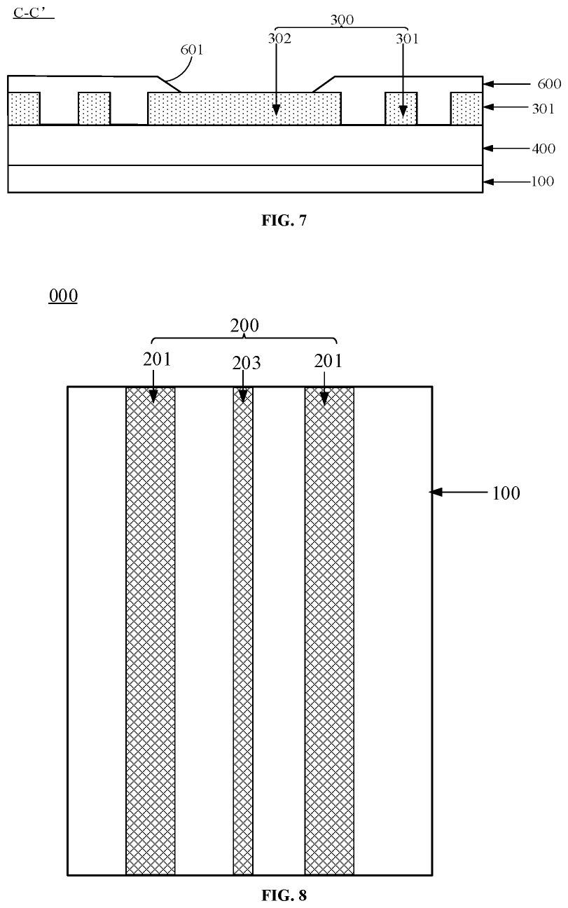

In some embodiments, as illustrated in FIG. 7, which is a schematic cross-sectional view of the display substrate illustrated in FIG. 3 at C-C′, the display substrate 000 also includes a second insulating layer 600 disposed on a side, distal from the substrate 100, of the second metal layer 300. The second insulating layer 600 has a plurality of second via 601 that correspond one-to-one with the plurality of pads 302. An orthographic projection of the second via 601 on the substrate 100 is within an orthographic projection of the corresponding pads 302 on the substrate 100. That is, at least a portion of the pad 302 in the display substrate 000 is exposed from a side of the display substrate 000 by the second via 601, such that the solder pin of a subsequent device (e.g., a light-emitting diode or chip 501) is welded to the pad 302 by the second via 601.

In the present disclosure, since each device in the light-emitting unit 500 in the display substrate 000 is opaque, in order to improve the transparency of the light-transmitting display panel, it is necessary to ensure that a distance between two adjacent rows of light-emitting units 500 is large and a distance between two adjacent columns of light-emitting units 500 is also large. For example, the distance between two adjacent rows of light-emitting units 500 and the distance between two adjacent columns of light-emitting units 500 range from 3.9 mm to 7.8 mm.

Further, each light-emitting unit 500 needs to be electrically connected to a plurality of first drive signal lines 201 within the display substrate 000. For example, each light-emitting unit 500 needs to be electrically connected to two anode drive signal lines 201a, one data signal line 201b, and one ground line 201c, which is referred to as a group of first drive signal lines electrically connected to the same light-emitting unit 500. Each light-emitting unit 500 within the same column of light-emitting units 500 is electrically connected to a group of first drive signal lines at the same time. Therefore, in order that the distance between two columns of adjacent light-emitting units 500 ranges from 3.9 mm to 7.8 mm, the distance between two groups of adjacent first drive signal lines needs to defined as ranging from 3.9 mm to 7.8 mm.

Similarly, each light-emitting unit 500 needs to be electrically connected to one second drive signal line 301 (i.e., the power signal line 301a) within the display substrate 000, and each light-emitting units 500 within the same row of light-emitting units 500 is electrically connected to one second drive signal line 301 at the same time. Therefore, in order that the distance between two rows of adjacent light-emitting units 500 ranges from 3.9 mm to 7.8 mm, the distance between two adjacent second drive signal lines needs to be defined as ranging from 3.9 mm to 7.8 mm.

It should be noted that only one light-emitting unit 500 is schematically depicted in the display substrate 000 illustrated in FIG. 6. The structure of the other light-emitting units 500 in the display substrate 000 and their connection methods to the display substrate 000 is referred to as the light-emitting unit 500, which is not described herein. The light-emitting diode in the light-emitting unit 500 is a light-emitting diode (LED), a sub-millimeter LED (Mini LED) or a micro LED (Micro LED). For example, a size of the LED is generally more than 300 microns, a size of the Mini LED generally ranges between 100 microns and 300 microns, and a size of the Micro LED is generally less than 100 microns.

In the embodiments of the present disclosure, both the first insulating layer 400 and the second insulating layer 600 include a passivation layer (not illustrated in the drawings) and a planarization layer (not illustrated in the drawings) which are stacked. The passivation layer is closer to the substrate 100 than the planarization layer. Herein, the passivation layer protects the metal layer, and the planarization layer improves the overall flatness of the transparent back to ensure that a subsequent device is normally welded on a side of the display substrate 000.

It should be noted that for the second metal layer 300, the second metal layer 300 needs to be disposed on a side of the planarization layer in the first insulating layer 400 that is back from the substrate 100, that is, the second metal layer 300 is prepared on the planarization layer, and in the case that widths of the signal lines distributed within the second metal layer 300 are larger, the bonding between the second metal layer 300 and the planarization layer is poor. For this reason, in the present disclosure, since the signal lines distributed within the second metal layer 300 are all grid-shaped signal lines, it can be ensured that the widths of the signal lines within the second metal layer 300 are smaller, thereby improving the bonding between the second metal layer 300 and the planarization layer.

In some embodiments, as illustrated in FIG. 8, FIG. 8 is a partial top view of a display substrate according to some embodiments of the present disclosure. In the display substrate 000, a first metal layer 200 further includes a virtual signal line 203 disposed between two adjacent first drive signal lines 201, the virtual signal line 203 being able to reduce a coupling capacitance between two adjacent first drive signal lines 201 in the display substrate 000, thereby further improving a transmission effect of a drive signal transmitted within the first drive signal line 201. Herein, at least a portion of the virtual signal line 203 is the grid-shaped signal line, which further improves the transmittance of ambient light by the display substrate 000.

In summary, the display substrate provided by the embodiments of the present disclosure includes a substrate, a first metal layer, a second metal layer, a first insulating layer, and a light-emitting unit. The first metal layer includes a plurality of first drive signal lines, and the second metal layer includes a plurality of second drive signal lines. Since at least a portion of each of the first drive signal lines and at least a portion of each of the second drive signal lines are grid-shaped signal lines, areas of the orthographic projections of the first drive signal line and the second drive signal line in the display substrate on the substrate are smaller. Thus, in the case that the display substrate is integrated within the transparent display device, the transmittance of the transparent display device to ambient light is effectively improved, resulting in a higher transparency of the transparent display device with such a display substrate integrated. Moreover, the first drive signal line and the second drive signal line within the display substrate have a lower reflection rate of the ambient light, and thus the integration of a black matrix within the display substrate is not necessary, which lowers difficulty in manufacturing the display substrate and reduces manufacturing cost of the display substrate.

The embodiments of the present disclosure also provide a transparent display device. The transparent display device is a transparent television, an outdoor billboard, or a shopping mall display board and includes a power supply assembly and a display substrate. The power supply assembly is configured to supply power to the display substrate to enable the display substrate to display, and the display substrate is any of the above-described display substrates. Exemplarily, the display substrate is the display substrate illustrated in FIG. 1, FIG. 3, FIG. 5, FIG. 6, or FIG. 8.

It should be noted that in the accompanying drawings, for clarity of the illustration, the dimension of the layers and regions may be scaled up. It may be understood that in the case that an element or layer is described as being “above” another element or layer, the described element or layer may be directly on the other element or layer, or an intermediate layer may be arranged between the described element or layer and the other element or layer. In addition, it may be understood that in the case that an element or layer is described as being “below” another element or layer, the described element or layer may be directly below the other element or layer, or one more intermediate layers or elements may be arranged between the described element or layer and the other element or layer. In addition, it may be further understood that in the case that a layer or element is described as being arranged “between” two layers or elements, the described layer or element may be the only layer between the two layers or elements, or one more intermediate layers or elements may be arranged between the described element or layer and the two layers or elements. In the whole specification described above, like reference numerals denote like elements.

In the present disclosure, the terms “first” and “second” are used for descriptive purposes only and are not to be construed as indicating or implying relative importance. The term “plurality” refers to two or more, unless specifically defined otherwise.

The foregoing descriptions are merely optional embodiments of the present disclosure, and are not intended to limit the present disclosure. Within the spirit and principles of the present disclosure, any modifications, equivalent substitutions, improvements, and the like are within the protection scope of the present disclosure.

1. A display substrate, comprising:
a substrate;
a first metal layer and a second metal layer on a side of the substrate, and a first insulating layer between the first and second metal layers; wherein the first metal layer comprises a plurality of first drive signal lines, and the second metal layer comprises a plurality of second drive signal lines; and
a plurality of light-emitting units electrically connected to the plurality of first drive signal lines and the plurality of second drive signal lines;
wherein at least a portion of each of the first drive signal lines and at least a portion of each of the second drive signal lines are grid-shaped signal lines.

2. The display substrate according to claim 1, wherein an extension direction of the first drive signal lines is intersected with an extension direction of the second drive signal lines, and a portion of each of the first drive signal lines that is overlapped with each of the second drive signal lines in an orthographic projection is the grid-shaped signal line.

3. The display substrate according to claim 2, wherein a portion of each of the second drive signal lines that is overlapped with each of the first drive signal lines in an orthographic projection is the grid-shaped signal line.

4. The display substrate according to claim 1, wherein the second metal layer further comprises a plurality of pads electrically connected to the light-emitting units, and a first adapter signal line; wherein
one end of the first adapter signal line being electrically connected to a first pad among the plurality of pads, and the other end of the first adapter signal line being electrically connected to the first drive signal line; and
at least a portion of the first adapter signal line is the grid-shaped signal line.

5. The display substrate according to claim 4, wherein the first metal layer further comprises a first electrode block electrically connected to the first drive signal line and connected to an end, facing away from the first pad, of the first adapter signal line.

6. The display substrate according to claim 5, wherein the second metal layer further comprises a second electrode block electrically connected to the end, facing away from the first pad, of the first adapter signal line, and the second electrode block is electrically connected to the first electrode block.

7. The display substrate according to claim 6, wherein the first insulating layer is provided with a first via; an orthographic projection of the first via on the substrate is within an orthographic projection of the first electrode block on the substrate; and at least a portion of the second electrode block is within the first via and electrically connected to the first electrode block.

8. The display substrate according to claim 4, wherein the second metal layer further comprises a second adapter signal line; wherein
one end of the second adapter signal line is electrically connected to a second pad among the plurality of pads, and the other end of the second adapter signal line is electrically connected to the second drive signal line; and
at least a portion of the second adapter signal line is the grid-shaped signal line.

9. The display substrate according to claim 8, wherein the second metal layer further comprises a third adapter signal line; wherein
both ends of the third adapter signal line are electrically connected to a third pad and a fourth pad of the plurality of pads respectively; and
at least a portion of the third adapter signal line is the grid-shaped signal line.

10. The display substrate according to claim 9, wherein the light-emitting unit comprises a chip and at least one light-emitting diode; and the plurality of pads comprise a first fixed pad group configured to be fixedly connected to the light-emitting diode, and a second fixed pad group configured to be fixedly connected to the chip;
wherein the first pad and the third pad are distributed in the first fixed pad group, and the first pad, the second pad, and the fourth pad are distributed in the second fixed pad group.

11. The display substrate according to claim 10, wherein an overlapping region is present between an orthographic projection of at least one of the first fixed pad group and the second fixed pad group on the substrate and an orthographic projection of the first drive signal line on the substrate.

12. The display substrate according to claim 10, wherein the plurality of first drive signal lines comprise an anode drive signal line, a data signal line, and a ground line; and the plurality of second drive signal lines comprise a power signal line; wherein
the first pad of the first fixed pad group is electrically connected to the anode drive signal line by the first adapter signal line;
the third pad of the first fixed pad group is electrically connected to the fourth pad of the second fixed pad group by the third adapter signal line;
one first pad of the second fixed pad group being electrically connected to the data signal line by one first adapter signal line, and another first pad of the second fixed pad group is electrically connected to the ground line by another first adapter signal line; and
the second pad of the second fixed pad group is electrically connected to the power signal line by the second adapter signal line.

13. The display substrate according to claim 4, further comprising: a second insulating layer disposed on a side of the second metal layer deviating from the substrate; the second insulating layer is provided with a plurality of second vias corresponding one-to-one to the plurality of pads; and orthographic projections of the second vias on the substrate are within orthographic projections of the corresponding pads on the substrate.

14. The display substrate according to claim 1, wherein the first metal layer further comprises a virtual signal line disposed between two adjacent the first drive signal lines, at least a portion of the virtual signal line being the grid-shaped signal line.

15. A transparent display device, comprising: a power supply assembly and a display substrate electrically connected to the power supply assembly; wherein
the display substrate includes:
a substrate;
a first metal layer and a second metal layer on a side of the substrate, and a first insulating layer between the first and second metal layers; wherein the first metal layer comprises a plurality of first drive signal lines, and the second metal layer comprises a plurality of second drive signal lines; and
a plurality of light-emitting units electrically connected to the plurality of first drive signal lines and the plurality of second drive signal lines;
wherein at least a portion of each of the first drive signal lines and at least a portion of each of the second drive signal lines are grid-shaped signal lines.

16. The transparent display device according to claim 15, wherein an extension direction of the first drive signal lines is intersected with an extension direction of the second drive signal lines, and a portion of each of the first drive signal lines that is overlapped with each of the second drive signal lines in an orthographic projection is the grid-shaped signal line.

17. The transparent display device according to claim 16, wherein a portion of each of the second drive signal lines that is overlapped with each of the first drive signal lines in an orthographic projection is the grid-shaped signal line.

18. The transparent display device according to claim 15, wherein the second metal layer further comprises a plurality of pads electrically connected to the light-emitting units, and a first adapter signal line; wherein
one end of the first adapter signal line being electrically connected to a first pad among the plurality of pads, and the other end of the first adapter signal line being electrically connected to the first drive signal line; and
at least a portion of the first adapter signal line is the grid-shaped signal line.

19. The transparent display device according to claim 18, wherein the first metal layer further comprises a first electrode block electrically connected to the first drive signal line and connected to an end, facing away from the first pad, of the first adapter signal line.

20. The transparent display device according to claim 19, wherein the second metal layer further comprises a second electrode block electrically connected to the end, facing away from the first pad, of the first adapter signal line, and the second electrode block is electrically connected to the first electrode block.
